(19) United States
(12) Patent Application Publication
(10) Pub. No.: US 2010/0227047 A1
(43) Pub. Date: Sep. 9, 2010

(54) Method for manufacturing organic light emitting diode

(75) Inventors: Meng-Tan CHIANG, Bade (TW); Tsung-Pei Tseng, Hsinchu (TW); Cheng-Hsiang CHUANG, Bade (TW); Jen-Sung HSU, Taipei (TW); Shieh-Jun WANG, Taipei (TW)

Correspondence Address: BACON & THOMAS, PLLC, 625 SLATERS LANE, FOURTH FLOOR, ALEXANDRIA, VA, 22314-1176, US

(73) Assignees: Yuan-Shin Materials Technology Corp., Taipei (TW); Chung-shan Institute of Science and Technology. Armaments Bureau. M.N.D., Longtan Township, Taoyuan County (TW)

(21) Appl. No.: 12/458,471

(22) Filed: Jul. 14, 2009

(30) Foreign Application Priority Data
Mar. 4, 2009 (TW) 098106956

(51) Int. Cl. H01J 9/00; B05D 5/06

(52) U.S. Cl. 427/66

(57) ABSTRACT

A method for manufacturing an organic light emitting diode (OLED) is disclosed, which comprises: (a) providing a substrate on which an anode is formed; (b) coating a Br-fluorocarbon precursor on the anode, and curing the Br-fluorocarbon precursor with UV light to form a fluorocarbon polymer film; (c) forming an organic light emitting structure on the fluorocarbon polymer film; and (d) forming a cathode on the organic light emitting structure. After coating, the remaining Br-fluorocarbon precursor can be recycled. Furthermore, the process of removing solvent is unnecessary. Therefore, the problem of waste can be prevented. Hence, it is possible to manufacture an OLED with a simple process and low cost by the method of the present invention.

### BACKGROUND OF THE INVENTION

1. Field of the Invention

The present invention relates to a method for manufacturing an organic light emitting diode and, more particularly, to a method for manufacturing an organic light emitting diode in which a UV-reactive fluorocarbon film is used as a buffer layer to reduce the operating voltage and improve the stability of the organic light emitting diode.

2. Description of Related Art

Currently, organic light emitting diodes (OLEDs) for flat panel displays are receiving considerable attention in several fields of electronics. A structure of an OLED is shown in FIG. 1, including: a substrate 101, an anode 102, an organic light emitting structure 107 and a cathode 106. Herein, the organic light emitting structure 107 includes an organic hole transporting layer 103, an organic emissive layer 104 and an organic electron transporting layer 105 in sequence. In other words, the organic emissive layer 104 is located between the organic hole transporting layer 103 and the organic electron transporting layer 105. The main function of the organic emissive layer 104 is to limit or control the efficient combination between electrons and holes, resulting in emission.

When a potential difference is applied between the anode 102 and the cathode 106, the anode is viewed as positive, and electrons will be injected into the organic electron transporting layer 105 and pass through the organic electron transporting layer 105 and the organic emissive layer 104. Meanwhile, holes will be injected into the organic hole transporting layer 103 and pass through the organic hole transporting layer 103. Finally, holes and electrons recombine at the junction between the organic hole transporting layer 103 and the organic emissive layer 104. When an electron drops from the conduction band back down to the valence band to combine with a hole, energy is released as light and that light is emitted in a direction from the transparent anode and then the substrate to a viewer.

However, in the term of operating stability and operating voltage, it is still necessary to improve OLEDs. A conventional anode is made of conductive and transparent oxides, such as Indium Tin Oxide (ITO). Indium Tin Oxide (ITO) has been widely applied in the development of anodes due to its transparency, excellent conductivity and high work function. However, in the case that a light emitting structure is directly grown on ITO, generally, poor current-voltage characteristics and low operating stability are incurred.

In order to improve the above-mentioned problems, it has been disclosed that the formation of a layer of medium called a buffer layer between ITO and the organic light emitting structure can improve the ITO characteristics and hole injection. Herein, a fluorocarbon film made of, for example, Telfon (Y. Gao et al., Appl. Phys. Lett. 82, 155, 2003) or CFx (L. S. Hung et al., Appl. Phys. Lett. 78, 673, 2001) can function as a buffer layer to improve the hole injection at the junction between ITO and the organic layer.

In the case of a fluorocarbon film being used as a buffer layer, the diffusion of indium from ITO can be prevented more efficiently so as to reduce the possibility of element degradation in addition to improve the hole injection at the junction between ITO and the organic layer. However, the fluorocarbon film is an insulating film and thereby causes a larger voltage drop in the OLED. Thereby, in general, the thickness of the fluorocarbon film is controlled in a range of 1 nm to 3 nm. However, the very low repeatability of the fluorocarbon ultra thin film is one of issues occurring in the case of using a fluorocarbon film as the buffer layer.

As known in the art, fluoride derivatives of poly(para-xylylenes) (PPX) can be employed in the fluorocarbon polymer film [—CF₂—C₆H₄—ₙZₙ-CF₂—], such as PPX—F(—CF₂—C₆H₄—CF₂—) and PPX(—CF₂—C₆F₄—CF₂—). In the process for manufacturing such fluorocarbon polymer film, (—CX₂—C₆H_{4l —}ₙZₙ-CX₂—)₂ dimers are first vaporized, and then pass through a needle valve via a transportation system and enter a high temperature thermal cracker to be cracked so as to form a radical. Subsequently, other byproducts generated in the cracking process are removed through a fractionation device, and the concentration of intermediates is controlled via a volumetric flow controller (VFC) to prevent intermediates from re-polymerization to form dimers. Finally, the gaseous intermediates as radical monomers are introduced into a deposition chamber equipped with a condenser to perform the formation of a film. However, some problems occur in the case of using a fluorocarbon film as the buffer layer, for example, the above-mentioned system for forming films is expensive. In addition, it is necessary to clean the reactor due to the generation of carbon black in heating the reactor for performing transfer polymerization, and the cost of such dimers is high.

In view of the above-mentioned problems, it is necessary to provide a simple, low-cost and reliable method for manufacturing a fluorocarbon film with improved repeatability for an OLED.

### SUMMARY OF THE INVENTION

One object of the present invention is to provide a method for manufacturing an organic light emitting diode (OLED), in which a fluorocarbon polymer film is formed by coating and UV-illuminating a Br-fluorocarbon precursor so as to improve the operating stability and enhance current intensity of the organic light emitting diode.

To achieve the object, the present invention provides a method for manufacturing an organic light emitting diode, including: (a) providing a substrate on which an anode is formed; (b) coating a Br-fluorocarbon precursor on the anode, and curing the Br-fluorocarbon precursor with UV light to form a fluorocarbon polymer film; (c) forming an organic light emitting structure on the fluorocarbon polymer film; and (d) forming a cathode on the organic light emitting structure.

In the present invention, a fluorocarbon polymer film is formed on the anode by coating and then UV-curing a UV-reactive Br-fluorocarbon precursor. In comparison to the fluorocarbon polymer film formed by a conventional method, i.e. plasma polymerization, sputtering or transfer polymerization, the fluorocarbon polymer film according to the present invention has improved smoothness, durability and adhesion. In addition, during coating, the remaining Br-fluorocarbon precursor can be recycled. Moreover, if the energy of UV light is controlled appropriately, the prior art process of removing solvent is unnecessary and thus the problem of waste can be prevented. Thereby, through the method for manufacturing an organic light emitting diode according to the present invention, it is possible to simplify the process for manufacturing an OLED and to reduce cost in addition to that a fluorocarbon polymer film can be formed as a buffer layer. Accordingly, the present invention provides a more convenient method for manufacturing an organic light emitting diode, enhances the smoothness and repeatability of the fluorocarbon polymer film, and reduces the operating voltage and improves the operating stability to improve the performance of the organic light emitting diode.

In the method for manufacturing an organic light emitting diode according to the present invention, the substrate is an insulating substrate and may be a transparent substrate or an opaque substrate. Preferably, the substrate is made of glass, plastic, ceramic or semiconductor materials.

In the method for manufacturing an organic light emitting diode according to the present invention, the anode may be any suitable optically transparent or optically opaque conductive layer, such as Indium Tin Oxide (ITO). In addition, preferably, the anode is made of a metal or a metal compound with a work function larger than 4.0 eV.

In the method for manufacturing an organic light emitting diode according to the present invention, after step (a), a surface treatment on the anode of the substrate may be selectively performed to modify the surface characteristics of the anode and improve the adhesion between the anode and the fluorocarbon polymer film. Herein, the surface treatment may be a corona treatment, UV radiation, or O₂ plasma surface treatment.

In the method for manufacturing an organic light emitting diode according to the present invention, any coating process commonly used in the art may be employed in step (b) to coat the Br-fluorocarbon precursor. Preferably, spin coating is employed in the present invention, and the spin coating rate may range from 500 rpm to 8000 rpm.

In the method for manufacturing an organic light emitting diode according to the present invention, the Br-fluorocarbon precursor is liquid and may include a Br—CF₂—C₆H₄—CF₂—Br monomer, a Br—CF₂—C₆F₄—CF₂—Br monomer, a mixture thereof, or other conjugate structures or heterocyclic structures containing bromine. Through a UV reactor, the Br-fluorocarbon precursor can be cured to form a fluorocarbon polymer film. Herein, the UV reactor can provide UV light that has a wavelength preferably ranging from 150 nm to 350 nm, and more preferably from 190 nm to 270 nm. In addition, the intensity of UV light may be in a range of 0.01 to 10 watts/cm², and the total exposure intensity of UV light is at least 300 mJ/cm².

In the method for manufacturing an organic light emitting diode according to the present invention, the fluorocarbon polymer film is made of fluorizated poly xylylene, and its structure is represented by the following formula (1),

(—CF₂—C₆X₄—CF₂—), (1)

wherein, X is H or F, and n is 1 or an integer larger than 1.

In addition, the thickness of the fluorocarbon polymer film preferably ranges from 5 nm to 40 nm, and more preferably from 8 nm to 30 nm.

In the method for manufacturing an organic light emitting diode according to the present invention, the material of the cathode is not particularly limited, and preferably is a material with a work function smaller than 4.0 eV, such as Ca or Li, or an alloy of a low work-function metal and a high work-function metal, such as a two-layered structure of Al/LiF.

Moreover, in the method for manufacturing an organic light emitting diode according to the present invention, the organic light emitting structure may further include an organic hole transporting layer, an organic emissive layer and an organic electron transporting layer, in which the organic hole transporting layer is formed on the fluorocarbon polymer film, the organic emissive layer is formed on the organic hole transporting layer, the organic electron transporting layer is formed on the organic emissive layer, and the organic emissive layer is located between the organic hole transporting layer and the organic electron transporting layer.

In the present invention, the material of the organic hole transporting layer is not particularly limited. Preferably, an aromatic tertiary amine containing at least one trivalent nitrogen atom bonding to carbon atoms and at least one aromatic ring is used in the organic hole transporting layer. The aromatic tertiary amine preferably may be arylamine, such as monarylamine, diarylamine or triarylamine.

In addition, the material of the organic emissive layer is not particularly limited and may be a luminescence material or a fluorescent material. Preferably, tri(8-quinolinolate-N1,08)-aluminum (Alq) is used in the organic emissive layer. More preferably, the organic emissive layer contains a host material and one or more kinds of fluorescent dyes as dopants. Herein, the emitting color of the organic light emitting diode can be modified by doping the host material with fluorescent dyes of various emission wavelengths.

Furthermore, the material of the organic electron transporting layer is not particularly limited. Preferably, metal chelated oxinoids or chelates of oxine (e.g. Alq₃) may be used therein.

Other objects, advantages, and novel features of the invention will become more apparent from the following detailed description when taken in conjunction with the accompanying drawings.

### BRIEF DESCRIPTION OF THE DRAWINGS

FIG. 1 is a cross-sectional view of a conventional organic light emitting diode;

FIG. 2 is a cross-sectional view of an organic light emitting diode according to the Example of the present invention;

FIG. 3 is a diagram of driving voltage versus current density according to the organic light emitting diodes of the Example and Comparative Example 1 of the present invention (-- for Example, - - - ◯ - - - for Comparative Example 1);

FIG. 4 is a diagram of driving voltage versus brightness according to the organic light emitting diodes of the Example and Comparative Example 1 of the present invention (-- for Example, - - - ◯ - - - for Comparative Example 1);

FIG. 5 is a diagram of aging time versus brightness according to the organic light emitting diodes of the Example and Comparative Example 1 of the present invention (- for Example, - - - for Comparative Example 1).

### DETAILED DESCRIPTION OF THE PREFERRED EMBODIMENT

### EXAMPLE

With reference to FIG. 2, there is shown a cross-sectional view of an organic light emitting diode according to the present embodiment. The method for manufacturing an organic light emitting diode according to the present embodiment is described hereafter.

First, a substrate 201, on which an anode 202 is formed, is provided. In the present embodiment, the substrate 201 is a glass substrate and the anode 202 is made of ITO. Next, the glass substrate on which ITO is formed is washed with a commercial cleaning agent in an ultrasonic cleaner, and then washed with deionized water, acetone and isopropyl alcohol in sequence, followed by O₂ plasma treatment on the surface of the anode 202 for 10 minutes so as to enhance the adhesion between the anode 202 and the fluorocarbon polymer film.

Subsequently, a Br-fluorocarbon precursor is coated on the anode 202 by spin coating at 3000 rpm. Herein, the Br-fluorocarbon precursor may be Br—CF₂—C₆H₄—CF₂—Br, Br—CF₂—C₆F₄—CF₂—Br or a mixture thereof. In the present embodiment, Br—CF₂—C₆H₄—CF₂—Br is used as a Br-fluorocarbon precursor.

Then, the Br-fluorocarbon precursor is cured with UV light to form a fluorocarbon polymer film 210. In the present embodiment, for the UV reactor, the illumination time is set to 38 seconds and the total exposure energy is set to 500 mJ/cm². Through exposure to UV light, the Br-fluorocarbon precursor can be cured to form a fluorocarbon polymer film 210 in the thickness of 15.9 nm.

Accordingly, the fluorocarbon polymer film 210 provided by the present embodiment is represented by the following formula (2),

(—CF₂—C₆H₄—CF₂—)ₙ (2)

in which, n is 1 or an integer larger than 1.

Subsequently, by thermal evaporation, an organic hole transporting layer 203, an organic emissive layer 204 and an organic electron transporting layer 205 are formed on the fluorocarbon polymer film in sequence as an organic light emitting structure 207. Herein, the organic hole transporting layer 203 is an NPB layer with a thickness of 50 nm, the thickness of the organic emissive layer 204 is 70 nm, and the organic electron transporting layer 205 is an Alq₃ layer with a thickness of 70 nm.

Finally, a cathode 206 is formed on the organic light emitting structure 207. Herein, the cathode 206 is formed by depositing Li (thickness: 0.5 nm) and Al (thickness: 200 nm) on the organic electron transporting layer (Alq₃ layer) 205 through evaporation.

Accordingly, the organic light emitting diode provided by the present embodiment includes: a substrate 201, an anode 202, a fluorocarbon polymer film 210, an organic light emitting structure 207 and a cathode 206. Herein, the organic light emitting structure 207 includes an organic hole transporting layer 203, an organic emissive layer 204 and an organic electron transporting layer 205. In addition, the organic hole transporting layer 203 is formed on the fluorocarbon polymer film 210, the organic emissive layer 204 is formed on the organic hole transporting layer 203, the organic electron transporting layer 205 is formed on the organic emissive layer 204, and the organic emissive layer 204 is located between the organic hole transporting layer 203 and the organic electron transporting layer 205.

### Comparative Example 1

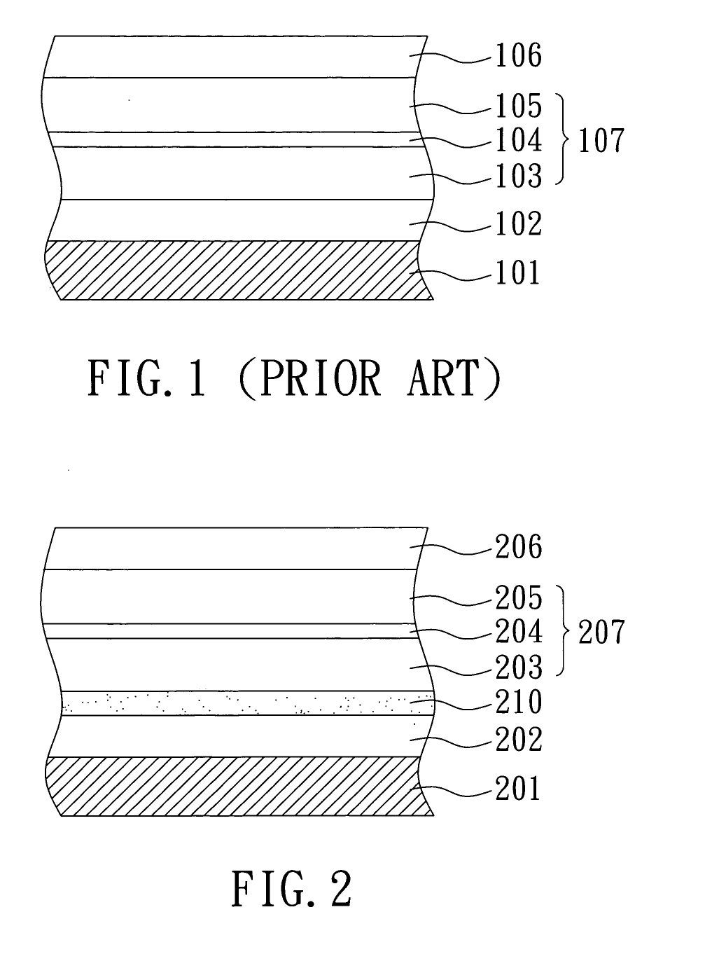

The structure and manufacturing method of the organic light emitting diode according to the comparative example are the same as those described in the Example, except that no fluorocarbon polymer film is formed in Comparative Example 1, as shown in FIG. 1.

### Test Example 1

### Current Density Versus Driving Voltage

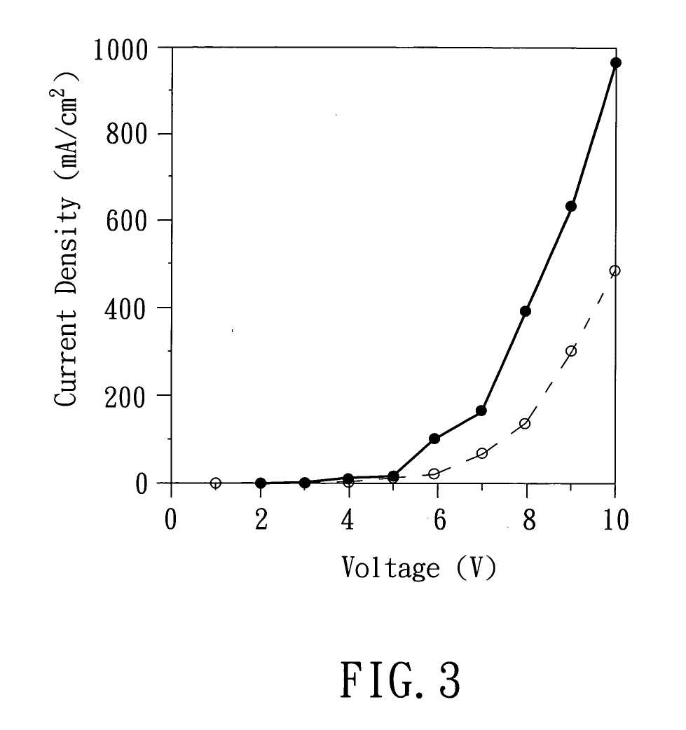

A driving voltage is applied between the anode and the cathode of each OLED according to the Example and Comparative Example to measure the relationship between current density and driving voltage, and the results are shown in FIG. 3. FIG. 3 shows that the OLED of the Example in which a fluorocarbon polymer film of a thickness of 15.9 nm is formed between the ITO anode and the organic hole transporting layer (NPB) has a sharper current density-driving voltage (I-V) curve, in comparison to the OLED according to Comparative Example 1 in which no fluorocarbon polymer film is formed. In other words, for the same current density, the driving voltage applied in the OLED according to the Example is lower in comparison to the OLED according to Comparative Example 1.

### Test Example 2

### Brightness Versus Driving Voltage

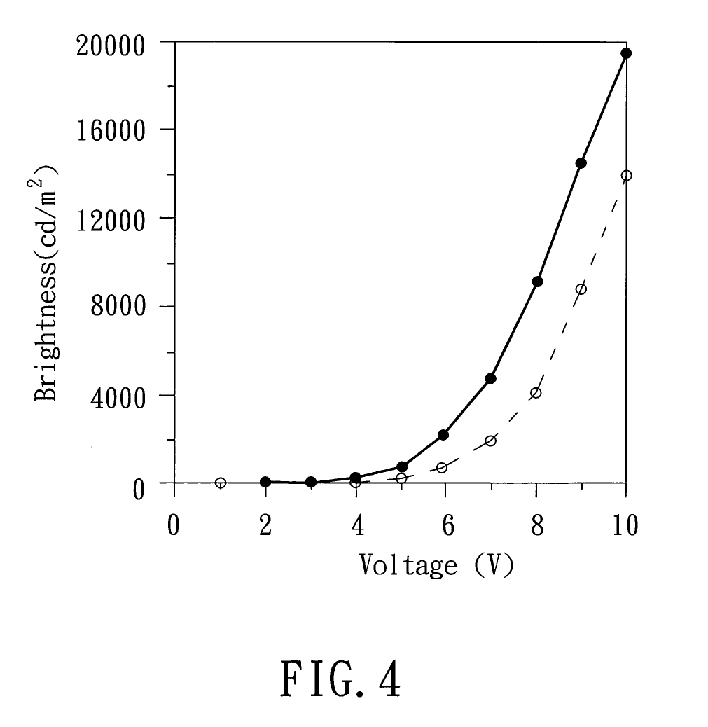

The diagram of brightness versus driving voltage of the OLEDs according to the Example and Comparative Example is shown in FIG. 4. It is shown that the OLED of the Example has a sharper brightness-driving voltage (B-V) curve in comparison to the OLED according to Comparative Example 1 in which no fluorocarbon polymer film is formed. According to the results, it can be further confirmed that the fluorocarbon polymer film can significantly improve the optic and electrical characteristics of an organic light emitting diode.

### Test Example 3

### Operating Stability

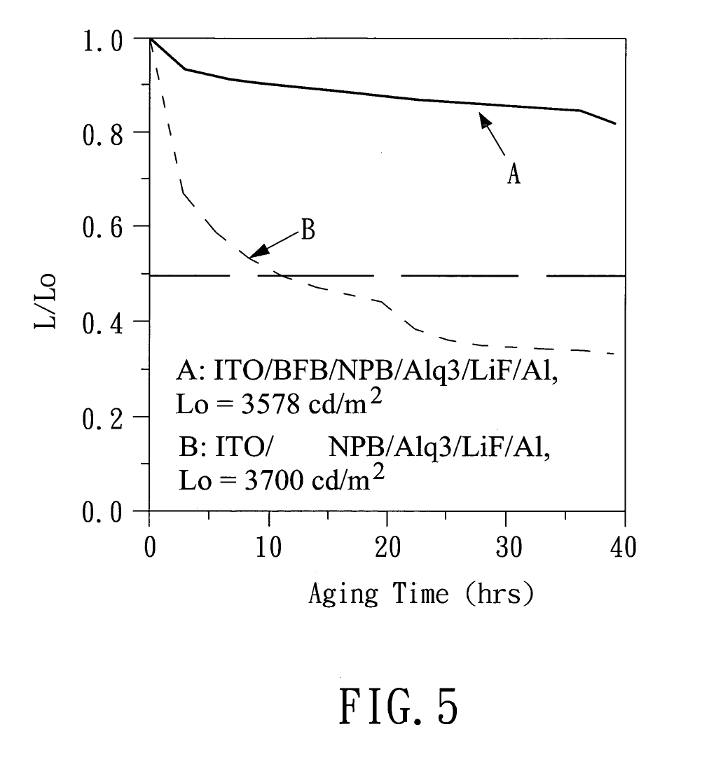

In general, the operating current of an OLED is 5 mA/cm². Herein, a steady current 125 mA/cm² is applied to more rapidly observe the aging of an OLED so as to evaluate the operating stability of OLEDs according to the Example and Comparative Example 1. The results are shown in FIG. 5. Herein, the initial brightness (Lo) of the OLED according to the Example is 3578 cd/m², and Lo of the OLED according to Comparative Example 1 is 3700 cd/m². It is shown that the change in the brightness of the OLED according to the Example is not significant after long-term operation, but the brightness of the OLED according to Comparative Example 1 decreases by half after 10-hour operation. Thereby, in comparison to the OLED of Comparative Example 1 in which no fluorocarbon polymer film is formed, the OLED of the Example has improved operating stability.

As aforementioned, the present invention provides a method for manufacturing an OLED in which a UV-reactive Br-fluorocarbon precursor is used to form a fluorocarbon polymer film with high repeatability. In the present invention, the remaining Br-fluorocarbon precursor can be recycled after the coating process and the process of removing solvent is unnecessary and thereby the problem of waste can be prevented. In addition, the method for manufacturing an OLED according to the present invention is simplified and compatible with a conventional method for manufacturing an OLED in the art. Moreover, the roughness of the fluorocarbon polymer film formed by UV-curing a Br-fluorocarbon precursor according to the present invention is very low. Meanwhile, the driving voltage is reduced and the operating stability is significantly improved due to the lower hole injection energy barrier of the fluorocarbon polymer film.

Although the present invention has been explained in relation to its preferred embodiment, it is to be understood that many other possible modifications and variations can be made without departing from the scope of the invention as hereinafter claimed.

What is claimed is:

1. A method for manufacturing an organic light emitting diode, comprising:
(a) providing a substrate on which an anode is formed;
(b) coating a Br-fluorocarbon precursor on the anode, and curing the Br-fluorocarbon precursor with UV light to form a fluorocarbon polymer film;
(c) forming an organic light emitting structure on the fluorocarbon polymer film; and
(d) forming a cathode on the organic light emitting structure.

2. The method as claimed in claim 1, wherein the Br-fluorocarbon precursor is Br—CF₂—C₆H₄—CF₂—Br, Br—CF₂—C₆F₄—CF₂—Br or a mixture thereof.

3. The method as claimed in claim 1, wherein the fluorocarbon polymer film is made of fluorizated poly xylylene.

4. The method as claimed in claim 1, wherein the fluorocarbon polymer film is represented by the following formula (1),
(—CF₂—C₆X₄—CF₂—)ₙ (1)
wherein, X is H or F, and n is 1 or an integer larger than 1.

5. The method as claimed in claim 1, wherein the substrate is an insulating substrate.

6. The method as claimed in claim 1, wherein the substrate is a transparent substrate or an opaque substrate.

7. The method as claimed in claim 6, wherein the transparent substrate is made of glass or plastic.

8. The method as claimed in claim 6, wherein the opaque substrate is made of a ceramic material or a semiconductor material.

9. The method as claimed in claim 1, wherein the anode is an optically transparent conductive layer.

10. The method as claimed in claim 1, wherein the anode is made of a metal or a metal compound with a work function larger than 4.0 eV.

11. The method as claimed in claim 1, wherein the cathode has a work function smaller than 4.0 eV.

12. The method as claimed in claim 1, wherein the thickness of the fluorocarbon polymer film ranges from 5 nm to 40 nm.

13. The method as claimed in claim 1, wherein the thickness of the fluorocarbon polymer film ranges from 8 nm to 30 nm.

14. The method as claimed in claim 1, wherein the wavelength of the UV light ranges from 150 nm to 350 nm.

15. The method as claimed in claim 1, wherein the wavelength of the UV light ranges from 190 nm to 270 nm.

16. The method as claimed in claim 1, wherein the intensity of the UV light ranges from 0.01 to 10 watts/cm².

17. The method as claimed in claim 1, wherein the total exposure intensity of the UV light is at least 300 mJ/cm².

18. The method as claimed in claim 1, wherein the organic light emitting structure comprises an organic hole transporting layer, an organic emissive layer and an organic electron transporting layer, wherein the organic hole transporting layer is formed on the fluorocarbon polymer film, the organic emissive layer is formed on the organic hole transporting layer, the organic electron transporting layer is formed on the organic emissive layer, and the organic emissive layer is located between the organic hole transporting layer and the organic electron transporting layer.

19. The method as claimed in claim 18, wherein the material of the organic hole transporting layer contains an aromatic tertiary amine compound.

20. The method as claimed in claim 18, wherein the material of the organic electron transporting layer contains a metal chelated oxinoid.
